(19) United States
(12) Patent Application Publication
(10) Pub. No.: US 2026/0324081 A1
(43) Pub. Date: Oct. 15, 2026

(54) DISPLAY DEVICE AND GATE-IN PANEL CIRCUIT

(71) Applicant: LG Display Co., Ltd., Seoul (KR)

(72) Inventors: Jinwoo PARK, Paju-si (KR); Sungwoo LEE, Paju-si (KR); Kyeongseob KWON, Paju-si (KR); Manki JI, Paju-si (KR)

(73) Assignee: LG Display Co., Ltd., Seoul (KR)

(21) Appl. No.: 19/537,273

(22) Filed: Feb. 11, 2026

(30) Foreign Application Priority Data
Apr. 10, 2025 (KR) 10-2025-0046460

(51) Int. Cl. H10D 86/60

(52) U.S. Cl. CPC H10D 86/60

(57) ABSTRACT

A display device includes a gate-in-panel circuit having a first transistor configured to selectively connect a first input node, receiving a first input signal, to an output node according to a voltage at a first control node, and a second transistor configured to selectively connect a second input node, receiving a second input signal, to the output node according to a voltage at a second control node. The circuit further includes at least one capacitor selected from: a first capacitor coupled between the first control node and the output node, and a second capacitor coupled between the second control node and the second input node. At least a portion of the first capacitor overlaps a region of the first transistor, and at least a portion of the second capacitor overlaps a region of the second transistor, thereby reducing layout area and improving integration within the panel.

### CROSS-REFERENCE TO RELATED APPLICATION

This application claims priority from Korean Patent Application No. 10-2025-0046460, filed on Apr. 10, 2025, which is hereby incorporated by reference for all purposes as if fully set forth herein.

### BACKGROUND

### Technical Field

Embodiments of the disclosure relate to a display device and a gate-in panel circuit.

### Description of Related Art

A display device may include a display panel in which a plurality of subpixels are disposed and a driving circuit for driving the plurality of subpixels. The display panel may include a display area capable of displaying an image and a non-display area in which an image is not displayed. Here, the non-display area is also referred to as a “bezel.”

Recently, requirements for enlarging the size of the display area and reducing the size of the non-display area have been increasing. However, there is difficulty in reducing the size of the non-display area.

### BRIEF SUMMARY

The present disclosure relates to a gate in panel output buffer circuit in which bootstrap capacitors are arranged to overlap corresponding transistors, including overlap with transistor channel regions. This configuration allows large effective capacitance to be achieved without increasing layout area, thereby supporting reduction of the non display region or bezel while maintaining stable gate signal output characteristics. The arrangement addresses the tradeoff between compact layout design and reliable gate driving performance.

In some implementations, the gate electrodes of the output transistors also function as capacitor electrodes, with comb shaped gate and capacitor patterns formed in adjacent metal layers. This structure increases capacitance density and enhances the bootstrap effect while simplifying the vertical layer stack and fabrication process by reducing the need for separate capacitor electrode formations. In other implementations, the first and second output transistors may share a single active semiconductor layer and may be configured using multiple parallel sub transistors to improve drive capability, signal stability, or process uniformity without increasing circuit area.

These structural and circuit level features may be applied individually or in various combinations to provide improved area efficiency, electrical performance, or manufacturability in a gate in panel architecture. The disclosed approaches support embedded gate driver circuits with reduced bezel size, improved signal output characteristics, and compatibility with standard display backplane fabrication processes.

Embodiments of the disclosure may provide a gate-in panel circuit having a structure capable of reducing a bezel and a display device including the same.

Embodiments of the disclosure may provide a gate-in panel circuit having a capacitor structure (bootstrap capacitor structure) capable of implementing large capacitance and a small bezel and a display device including the same.

Embodiments of the disclosure may provide a gate-in panel circuit having excellent signal output characteristics and a display device including the same.

Embodiments of the disclosure may provide a gate-in panel circuit having a structure capable of process optimization and a display device including the same.

Technical benefits of embodiments of the disclosure are not limited to those set forth herein, and other unmentioned benefits would be apparent to one of ordinary skill in the art from the following description.

A display device according to embodiments of the disclosure includes a first transistor configured to control a connection between a first input node to which a first input signal is input and an output node from which an output signal is output, according to the voltage of a first control node, and a second transistor configured to control a connection between a second input node to which a second input signal is input and the output node, according to the voltage of a second control node.

The display device according to embodiments of the disclosure may further include at least one of a first capacitor between the first control node and the output node and a second capacitor between the second control node and the second input node, at least a portion of the first capacitor may overlap at least a portion of the first transistor, and at least a portion of the second capacitor may overlap at least a portion of the second transistor.

A gate-in panel circuit according to embodiments of the disclosure includes a first transistor controlling a connection between a first input node to which a first input signal is input and an output node from which an output signal is output, according to the voltage of a first control node, and a second transistor controlling a connection between a second input node to which a second input signal is input and the output node, according to the voltage of a second control node.

The gate-in panel circuit according to embodiments of the disclosure may further include at least one of a first capacitor having at least a portion disposed on a first channel region of the first transistor and a second capacitor having at least a portion disposed on a second channel region of the second transistor. At least a portion of the first capacitor may overlap the first channel region, and at least a portion of the second capacitor may overlap the second channel region.

According to embodiments of the disclosure, a gate-in panel circuit having a structure capable of reducing a bezel and a display device including the same may be provided.

According to embodiments of the disclosure, a gate-in panel circuit having a capacitor structure (bootstrap capacitor structure) capable of implementing large capacitance and a small bezel and a display device including the same may be provided.

According to embodiments of the disclosure, a gate-in panel circuit having excellent signal output characteristics and a display device including the same may be provided.

According to embodiments of the disclosure, a gate-in panel circuit having a structure capable of process optimization and a display device including the same may be provided.

The effects of the disclosure are not limited to the foregoing objects, and other effects will be apparent to one of ordinary skill in the art from the following detailed description.

### BRIEF DESCRIPTION OF THE SEVERAL VIEWS OF THE DRAWINGS

The disclosure will be more fully understood from the following detailed description and the accompanying drawings, which are provided for illustration only and are not intended to limit the disclosure.

FIG. 1 illustrates a display device according to embodiments of the disclosure.

FIG. 2 illustrates a display panel according to an embodiment of the disclosure.

FIG. 3 is a plan view illustrating a display panel according to embodiments of the disclosure.

FIGS. 4 and 5 illustrate a gate-in panel circuit according to embodiments of the disclosure.

FIGS. 6 and 7 illustrate an arrangement area of an output buffer circuit of a gate-in panel circuit according to embodiments of the disclosure.

FIGS. 8 to 10 illustrate a planar structure and a vertical structure of an arrangement area of an output buffer circuit of a gate-in panel circuit according to embodiments of the disclosure.

FIG. 11 is a cross-sectional view in a display area of a display panel according to embodiments of the disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements, etc., but is used merely to distinguish the corresponding element from other elements.

When it is mentioned that a first element “is connected or coupled to”, “contacts or overlaps”, etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc., each other via a fourth element. Here, the second element may be included in at least one of two or more elements that “are connected or coupled to”, “contact or overlap”, etc., each other.

To further elaborate, as used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The terms "coupled" and "in contact" should be interpreted in the same manner.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

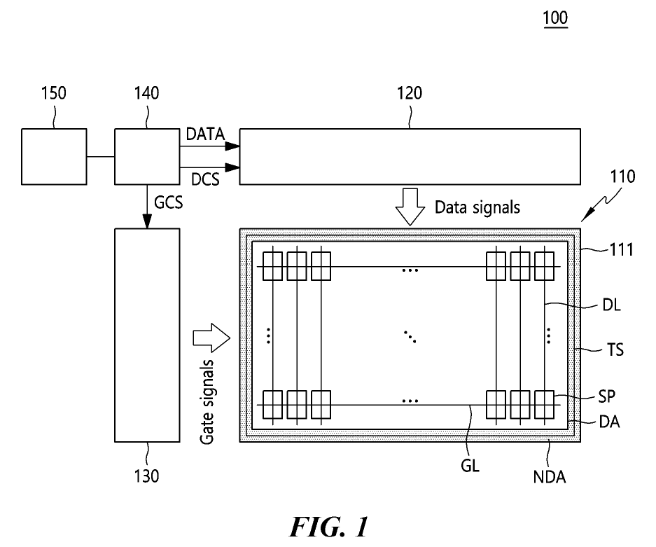

FIG. 1 illustrates a display device 100 according to embodiments of the disclosure.

Referring to FIG. 1, a display device 100 according to embodiments of the disclosure may include a display panel 110 and a display driving circuit for driving the display panel 110. The display driving circuits may include a data driving circuit 120, a gate driving circuit 130, and a controller 140.

The display panel 110 may include a display area DA in which an image may be displayed and a non-display area NDA that is an outer area of the display area DA. The display panel 110 may include a substrate 111, a plurality of subpixels SP disposed on the substrate 111, and a plurality of signal lines. The substrate 111 may include a display area DA and a non-display area NDA.

The display area DA may include a plurality of subpixels SP for image display. The non-display area NDA may include a pad area to which a driving circuit is connected.

The display device 100 may be a display device in which the display panel 110 does not emit light by itself (e.g., a liquid crystal display device) or a self-emitting display device that emits light by itself through light emitting elements disposed on the display panel 110.

When the display device 100 is a self-emitting display device, e.g., the display device 100 may be an organic light emitting display device in which a light emitting element is implemented as an organic light emitting diode (OLED), an inorganic light emitting display device in which a light emitting element is implemented as an inorganic material-based light emitting diode, a quantum dot display device in which a light emitting element is implemented as a quantum dot that is a semiconductor crystal emitting light by itself, or a micro light emitting diode (LED) display device or a mini LED display device.

Various types of display signal lines may be disposed on the substrate 111 of the display panel 110 to drive the plurality of subpixels SP. For example, the various types of display signal lines may include a plurality of data lines DL delivering data signals (also referred to as data voltages or image signals) to the plurality of subpixels SP and a plurality of gate lines GL delivering gate signals (also referred to as scan signals) to the plurality of subpixels SP.

The data driving circuit 120 may receive image data DATA in a digital form from the controller 140, convert the received image data DATA into a data signal (data voltage) in an analog form, and output the data signal to the plurality of data lines DL.

The gate driving circuit 130 may receive a first gate voltage corresponding to a turn-on level voltage and a second gate voltage corresponding to a turn-off level voltage together with various gate driving control signals GCS, generate gate signals including a section having the first gate voltage and a section having the second gate voltage for a predetermined time (e.g., one frame time), and supply the generated gate signals to the plurality of gate lines GL. For example, the turn-on level voltage may be a high level voltage, and the turn-off level voltage may be a low level voltage. As another example, the turn-on level voltage may be a low level voltage, and the turn-off level voltage may be a high level voltage.

The gate driving circuit 130 may be embedded in the display panel 110 as a gate-in panel (GIP) type. The gate driving circuit 130 may be disposed in the non-display area NDA or the display area DA of the display panel 110.

The controller 140 may supply image data DATA to the data driving circuit 120 based on input image data received from a host system 150. The controller 140 may supply a data driving control signal DCS to the data driving circuit 120 and supply a gate driving control signal GCS to the gate driving circuit 130.

The display device 100 according to embodiments of the disclosure may further include a touch sensor TS disposed in the display area DA and a touch sensing circuit sensing a touch by the touch sensor TS.

The display device 100 according to embodiments of the disclosure may be a terminal such as a smartphone or a tablet, a monitor or a television (TV), or may be a vehicle display device installed inside a vehicle. However, embodiments of the disclosure are not limited thereto.

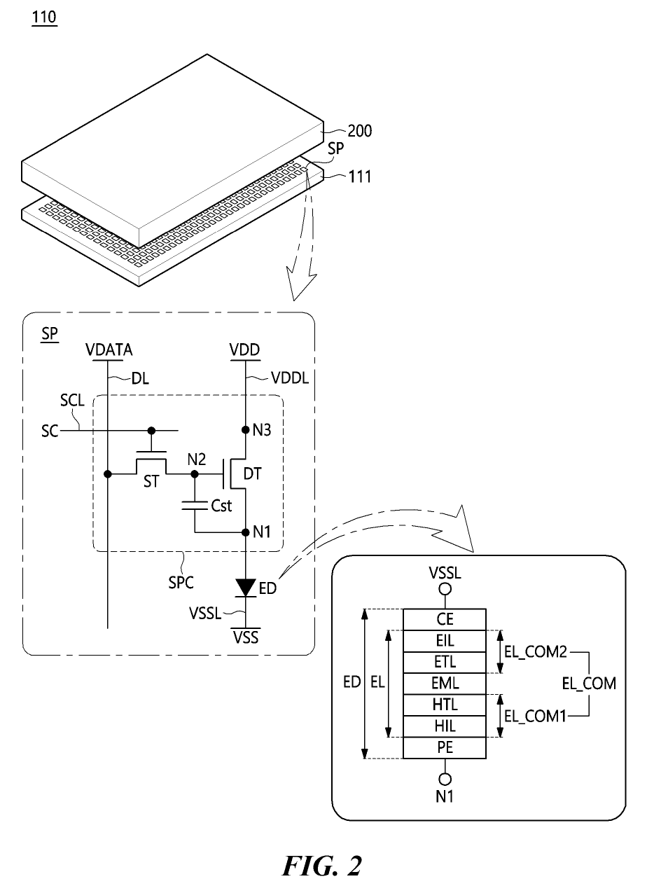

FIG. 2 illustrates the display panel 110 according to embodiments of the disclosure.

Referring to FIG. 2, the display panel 110 according to embodiments of the disclosure may include a substrate 111 on which a plurality of subpixels SP are disposed and an encapsulation layer 200 on the substrate 111. The encapsulation layer 200 may also be referred to as an encapsulation substrate or an encapsulation unit.

Each of the plurality of subpixels SP of the display device 100 according to embodiments of the disclosure may include a light emitting element ED and a subpixel circuit SPC for driving the light emitting element ED by supplying a driving current to the light emitting element ED at a predetermined timing.

The subpixel circuit SPC may include a driving transistor DT for driving the light emitting element ED, a scan transistor ST turned on or off according to a scan signal SC, a storage capacitor Cst for maintaining a constant voltage for a predetermined period of time, or the like.

A data signal VDATA that is an image signal and a scan signal SC that is one type of gate signal may be applied to the subpixel SP. A common voltage may be applied to the subpixel SP. The common voltage may include a first common voltage VSS and a second common voltage VDD. For example, the first common voltage VSS may be a low potential power voltage, and the second common voltage VDD may be a high-potential power voltage.

The light emitting element ED may include a pixel electrode PE, an intermediate layer EL, and a common electrode CE. The intermediate layer EL may be disposed between the pixel electrode PE and the common electrode CE. For example, the pixel electrode PE may be an electrode disposed in each subpixel SP, and the common electrode CE may be an electrode commonly disposed in all the subpixels SP. For example, the pixel electrode PE may be an anode electrode, and the common electrode CE may be a cathode electrode. As another example, the pixel electrode PE may be a cathode electrode, and the common electrode CE may be an anode electrode. For example, the intermediate layer EL may include an organic material.

When the light emitting element ED is an organic light emitting element, the intermediate layer EL may include a light emitting layer EML and a common intermediate layer EL_COM. The common intermediate layer EL_COM may include a first common intermediate layer EL_COM1 between the pixel electrode PE and the emission layer EML and a second common intermediate layer EL_COM2 between the emission layer EML and the common electrode CE. In an example, the first common intermediate layer EL_COM1 may include a hole injection layer (HIL) and a hole transport layer (HTL), and the second common intermediate layer EL_COM2 may include an electron transport layer (ETL) and an electron injection layer (EIL).

The emission layer EML may be disposed for each subpixel SP or commonly disposed across the plurality of subpixels SP, and the common intermediate layer EL_COM may be commonly disposed across the plurality of subpixels SP.

For example, the common electrode CE may be electrically connected to a first common voltage line VSSL that is one type of display power line. The first common voltage VSS that is one type of common voltage may be applied to the common electrode CE through the first common voltage line VSSL. The pixel electrode PE may be electrically connected directly or indirectly to a first node N1 of the driving transistor DT of each subpixel SP. The first common voltage VSS may also be described as a low potential power voltage or a low-potential voltage, and the first common voltage line VSSL may also be described as a low potential power voltage line or a low-potential voltage line.

The driving transistor DT may be connected between a second common voltage line VDDL that is another type of display power line and the light emitting element ED. The driving transistor DT may include a first node N1, a second node N2, and a third node N3. The first node N1 may be electrically connected to the light emitting element ED, a data signal VDATA may be applied to the second node N2, and a second common voltage VDD that is another type of common voltage may be applied to the third node N3 from the second common voltage line VDDL. The driving transistor DT may be connected between the first node N1 and the third node N3. Here, the second common voltage VDD may also be described as a high-potential power voltage or a high-potential voltage, and the second common voltage line VDDL may also be described as a high-potential power voltage line or a high-potential voltage line. The second node N2 may be a gate node, the first node N1 may be a source node or a drain node, and the third node N3 may be a drain node or a source node.

The scan transistor ST may be a switching transistor for delivering a data signal VDATA that is an image signal to the second node N2 that is a gate node of the driving transistor DT. The scan transistor ST may control an electrical connection between the second node N2 of the driving transistor DT and a data line DL by being turned on or off by a scan signal SC that is one type of gate signal applied through a scan line SCL that is one type of gate line GL. The scan transistor ST may be connected between the data line DL and the second node N2 of the driving transistor DT.

The storage capacitor Cst may be electrically connected between the first node N1 and second node N2 of the driving transistor DT.

Each of the driving transistor DT and the scan transistor ST may be an n-type transistor or a p-type transistor. The subpixel circuit SPC may further include one or more transistors and/or one or more capacitors, unlike as illustrated in FIG. 2. The display panel 110 may have a top emission structure or a bottom emission structure.

Circuit elements (e.g., the light emitting element ED including an organic material) within each subpixel SP are vulnerable to external moisture or oxygen, so an encapsulation layer 200 may be disposed on the light emitting element ED. The encapsulation layer 200 may be configured in various forms so that the light emitting elements ED do not contact moisture or oxygen. For example, the encapsulation layer 200 may be composed of two or more layers in which an organic layer and an inorganic layer are alternately stacked.

The display device 100 according to embodiments of the disclosure may further include a touch sensor layer in which a touch sensor is formed to provide a touch sensing function. The touch sensor may be composed of a plurality of touch electrodes.

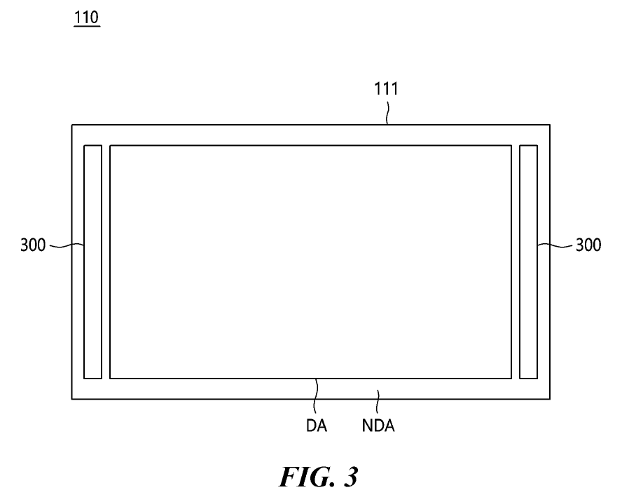

FIG. 3 is a plan view illustrating the display panel 110 according to embodiments of the disclosure.

Referring to FIG. 3, the display panel 110 according to embodiments of the disclosure may include the display area DA and the non-display area NDA. The substrate 111 of the display panel 110 may also be said to include the display area DA and the non-display area NDA.

Referring to FIG. 3, e.g., the gate driving circuit 130 may be implemented as a gate-in panel circuit 300 in the form embedded in the display panel 110.

In an example, the gate-in panel circuit 300 may be disposed in the non-display area NDA and may be disposed on at least one of one side and the other side of the display area DA. As another example, the gate-in panel circuit 300 may also be disposed in the display area DA.

Hereinafter, the gate-in panel circuit 300 included in the display device 100 according to embodiments of the disclosure is described in more detail.

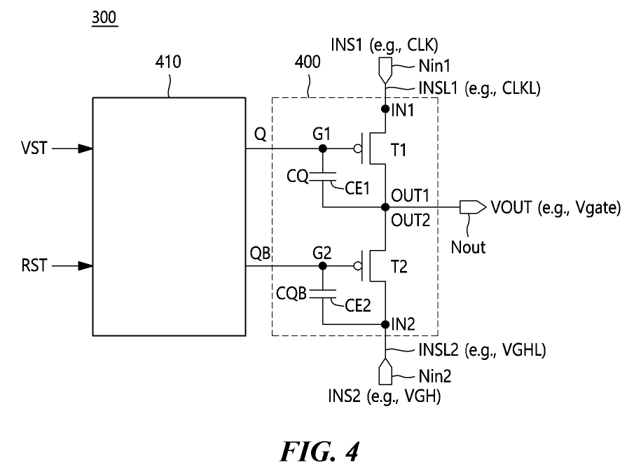

FIG. 4 illustrates the gate-in panel circuit 300 according to embodiments of the disclosure.

Referring to FIG. 4, the gate-in panel circuit 300 according to embodiments of the disclosure may include an output buffer circuit 400 configured to output an output signal VOUT of a desired form at a desired timing and a control circuit 410 controlling an operation and a state of the output buffer circuit 400.

The output buffer circuit 400 may be configured to receive two input signals INS1 and INS2 and output an output signal VOUT, and may include a first transistor T1 and a second transistor T2 for this purpose. The first transistor T1 and the second transistor T2 may be connected between a first input node Nin1 and a second input node Nin2.

The first input node Nin1 may be a node to which the first input signal INS1 is input, the second input node Nin2 may be a node to which the second input signal INS2 is input, and the output node Nout may be a node from which the output signal VOUT is output.

The first input node Nin1 may be electrically connected to a first input signal line INSL1 to which the first input signal INS1 is applied, the second input node Nin2 may be electrically connected to a second input signal line INSL2 to which the second input signal INS2 is applied, and the output node Nout may be electrically connected to a gate line GL from which the output signal VOUT is output.

The first transistor T1 may be connected between the first input node Nin1 and the output node Nout. The first transistor T1 may include a first input electrode IN1, a first output electrode OUT1, and a first gate electrode G1. The first input electrode IN1 may be electrically connected to the first input node Nin1, the first output electrode OUT1 may be electrically connected to the output node Nout, and the first gate electrode G1 may be electrically connected to the first control node Q.

In an example, the first input electrode IN1 may be a drain electrode, and the first output electrode OUT1 may be a source electrode. As another example, the first input electrode IN1 may be a source electrode, and the first output electrode OUT1 may be a drain electrode.

The second transistor T2 may be connected between the second input node Nin2 and the output node Nout. The second transistor T2 may include a second input electrode IN2, a second output electrode OUT2, and a second gate electrode G2. The second input electrode IN2 may be electrically connected to the second input node Nin2, the second output electrode OUT2 may be electrically connected to the output node Nout, and the second gate electrode G2 may be electrically connected to the second control node QB.

In an example, the second input electrode IN2 may be a drain electrode, and the second output electrode OUT2 may be a source electrode. As another example, the second input electrode IN2 may be a source electrode, and the second output electrode OUT2 may be a drain electrode.

The first transistor T1 may be turned on or turned off according to the voltage of the first control node Q corresponding to the first gate electrode G1, and the second transistor T2 may be turned on or turned off according to the voltage of the second control node QB corresponding to the second gate electrode G2.

The control circuit 410 may control the voltage of each of the first control node Q and the second control node QB. To this end, the control circuit 410 may include a plurality of transistors. The control circuit 410 may further include at least one capacitor. The control circuit 410 may receive a start signal VST and a reset signal RST. The control circuit 410 may control the voltage of each of the first control node Q and the second control node QB by controlling charging and discharging of each of the first control node Q and the second control node QB.

The voltage of the first control node Q and the voltage of the second control node QB may have different voltage levels. For example, when the voltage of the first control node Q is a high level voltage, the voltage of the second control node QB may be a low level voltage. When the voltage of the first control node Q is a low level voltage, the voltage of the second control node QB may be a high level voltage.

Accordingly, at any time, an on-off state of the first transistor T1 and the second transistor T2 may be opposite. For example, the first transistor T1 may be in a turn-on state, and the second transistor T2 may be in a turn-off state. The first transistor T1 may be in a turn-off state, and the second transistor T2 may be in a turn-on state.

The first input signal INS1 and the second input signal INS2 may be different signals from each other. The first input signal INS1 may include an section having a voltage different from the voltage of the second input signal INS2. Accordingly, a voltage level of the output signal VOUT output through the output buffer circuit 400 may change according to gate driving characteristics.

For example, the first input signal INS1 may be a signal whose voltage level varies or may be a voltage having a first voltage level. The second input signal INS2 may be a signal whose voltage level is constant or may be a voltage having a second voltage level different from the first voltage level.

As a more specific example, the first input signal INS1 may be a clock signal CLK, and the first input signal line INSL1 may be a clock signal line CLKL. The second input signal INS2 may be a gate high level voltage VGH, and the second input signal line INSL2 may be a gate high level voltage line VGHL. In this case, each of the first transistor T1 and the second transistor T2 may be a p-type transistor.

As another example, the first input signal INS1 may be a clock signal CLK, and the first input signal line INSL1 may be a clock signal line CLKL. The second input signal INS2 may be a gate low level voltage VGL, and the second input signal line INSL2 may be a gate low level voltage line VGLL. In this case, each of the first transistor T1 and the second transistor T2 may be an n-type transistor.

For example, the output signal VOUT may be a gate signal Vgate applied to the gate line GL. In an example, the gate signal Vgate may be a scan signal SC applied to a gate electrode of the scan transistor ST and the scan line SCL of FIG. 2. The scan line SCL may be one type of gate line GL, and the scan signal SC may be one type of gate signal Vgate.

As described above, the first transistor T1 may be configured to control a connection between the first input node Nin1 to which the first input signal INS1 is input and the output node Nout from which the output signal VOUT is output, according to the voltage of the first control node Q controlled by the control circuit 410.

The second transistor T2 may be configured to control a connection between the second input node Nin2 to which the second input signal INS2 is input and the output node Nout, according to the voltage of the second control node QB controlled by the control circuit 410.

During a first period, when the first transistor T1 is turned on according to the voltage of the first control node Q, the first transistor T1 may output the first input signal INS1 to the output node Nout. In this case, the second transistor T2 may be in a turn-off state.

During a second period different from the first period, when the second transistor T2 is turned on according to the voltage of the second control node QB, the second transistor T2 may output the second input signal INS2 to the output node Nout. In this case, the first transistor T1 may be in a turn-off state.

Referring to the example of FIG. 4, an operation of the output buffer circuit 400 is described as follows.

FIG. 4 illustrates an example in which the first transistor T1 and the second transistor T2 are p-type transistors. A p-type transistor may be turned on when a gate voltage has a low level voltage, and may be turned off when a gate voltage has a high level voltage. In other words, in the case of a p-type transistor, a turn-on level voltage may be a low level voltage, and a turn-off level voltage may be a high level voltage.

Unlike this, the first transistor T1 and the second transistor T2 may also be n-type transistors. An n-type transistor may be turned on when a gate voltage has a high level voltage, and may be turned off when a gate voltage has a low level voltage. In other words, in the case of an n-type transistor, a turn-on level voltage may be a high level voltage, and a turn-off level voltage may be a low level voltage.

Referring to FIG. 4, during the first period, the first control node Q may have a low level voltage, and the second control node QB may have a high level voltage. In this case, the first transistor T1 is turned on, and the second transistor T2 is turned off. Accordingly, the first input signal INS1 may be output to the output node Nout through the first transistor T1.

Referring to FIG. 4, during the second period that is a preceding period or a subsequent period of the first period, the first control node Q may have a high level voltage, and the second control node QB may have a low level voltage. In this case, the first transistor T1 is turned off, and the second transistor T2 is turned on. Accordingly, the second input signal INS2 may be output to the output node Nout through the second transistor T2.

Referring to FIG. 4, as the first period and the second period progress, the output signal VOUT may have a first voltage level (e.g., low level voltage) of the first input signal INS1 during the first period and may have a second voltage level (e.g., high level voltage) of the second input signal INS2 during the second period.

Referring to FIG. 4, the output buffer circuit 400 of the gate-in panel circuit 300 according to embodiments of the disclosure may further include at least one of a first capacitor CQ and a second capacitor CQB.

Each of the first capacitor CQ and the second capacitor CQB may correspond to a bootstrap capacitor.

The first capacitor CQ may be disposed (formed, connected) between the first control node Q and the output node Nout. In other words, the first capacitor CQ may be disposed (formed, connected) between the first gate electrode G1 and the first output electrode OUT1 of the first transistor T1.

The first capacitor CQ may include a first capacitor electrode CE1 integrally formed with or electrically connected to the first output electrode OUT1. The first capacitor CQ may be formed between the first gate electrode G1 and the first capacitor electrode CE1.

The second capacitor CQB may be disposed (formed, connected) between the second control node QB and the second input node Nin2. In other words, the second capacitor CQB may be disposed (formed, connected) between the second gate electrode G2 and the second input electrode IN2 of the second transistor T2.

The second capacitor CQB may include a second capacitor electrode CE2 integrally with or electrically connected to the second input electrode IN2. The second capacitor CQB may be formed between the second gate electrode G2 and the second capacitor electrode CE2.

Referring to FIG. 4, by connecting (disposing, forming) the first capacitor CQ between the first gate electrode G1 and the first output electrode OUT1 of the first transistor T1, the first transistor T1 may stably perform a switching operation, and signal output characteristics through the first transistor T1 may be enhanced.

As a capacitance of the first capacitor CQ increases, signal output characteristics through the first transistor T1 may be further enhanced. As an area of the first capacitor CQ increases, the capacitance of the first capacitor CQ may increase.

By connecting (disposing, forming) the second capacitor CQB between the second gate electrode G2 and the second input electrode IN2 of the second transistor T2, the second transistor T2 may stably perform a switching operation, and signal output characteristics through the second transistor T2 may be enhanced.

As a capacitance of the second capacitor CQB increases, signal output characteristics through the second transistor T2 may be further enhanced. As an area of the second capacitor CQB increases, the capacitance of the second capacitor CQB may increase.

The enhancement in signal output characteristics by at least one of the first capacitor CQ and the second capacitor CQB may enhance gate driving performance of the gate-in panel circuit 300, and consequently, image display quality of the display device 100 may be enhanced.

The display panel 110 according to embodiments of the disclosure includes the substrate 111 including the display area DA and the non-display area NDA, and the gate-in panel circuit 300 may be disposed on the substrate 111.

In an example, the gate-in panel circuit 300 may be located in the non-display area NDA. Accordingly, the first transistor T1, the second transistor T2, the first capacitor CQ, and the second capacitor CQB included in the output buffer circuit 400 of the gate-in panel circuit 300 may be disposed on the substrate 111 and located in the non-display area NDA.

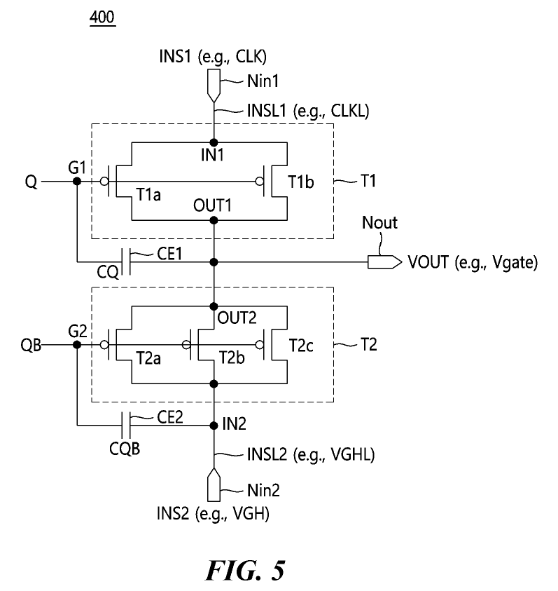

FIG. 5 illustrates the output buffer circuit 400 of the gate-in panel circuit 300 according to embodiments of the disclosure. Hereinafter, FIG. 4 is also referred to together, and description overlapping the description of FIG. 4 may be omitted.

Referring to FIG. 5, at least one of the first transistor T1 and the second transistor T2 may be composed of two or more sub transistors.

For example, the first transistor T1 may include a first sub transistor T1a and a second sub transistor T1b.

The gate electrode of the first sub transistor T1a and the gate electrode of the second sub transistor T1b may be commonly connected to the first control node Q, the input electrode of the first sub transistor T1a and the input electrode of the second sub transistor T1b may be commonly connected to the first input node Nin1, and the output electrode of the first sub transistor T1a and the output electrode of the second sub transistor T1b may be commonly connected to the output node Nout.

According to the voltage of the first control node Q, the first sub transistor T1a and the second sub transistor T1b may be turned on together or turned off together.

The first sub transistor T1a and the second sub transistor T1b may be connected in parallel.

By configuring the first transistor T1 with the first sub transistor T1a and the second sub transistor T1b, the first transistor T1 may operate more stably, and performance of the first transistor T1 may be further enhanced.

For example, the second transistor T2 may include a third sub transistor T2a, a fourth sub transistor T2b, and a fifth sub transistor T2c.

The gate electrode of the third sub transistor T2a, the gate electrode of the fourth sub transistor T2b, and the gate electrode of the fifth sub transistor T2c may be commonly connected to the second control node QB, the input electrode of the third sub transistor T2a, the input electrode of the fourth sub transistor T2b, and the input electrode of the fifth sub transistor T2c may be commonly connected to the second input node Nin2, and the output electrode of the third sub transistor T2a, the output electrode of the fourth sub transistor T2b, and the output electrode of the fifth sub transistor T2c may be commonly connected to the output node Nout.

According to the voltage of the second control node QB, the third sub transistor T2a, the fourth sub transistor T2b, and the fifth sub transistor T2c may be turned on together or turned off together.

The third sub transistor T2a, the fourth sub transistor T2b, and the fifth sub transistor T2c may be connected in parallel.

By configuring the second transistor T2 with the third sub transistor T2a, the fourth sub transistor T2b, and the fifth sub transistor T2c, the second transistor T2 may operate more stably, and performance of the second transistor T2 may be further enhanced.

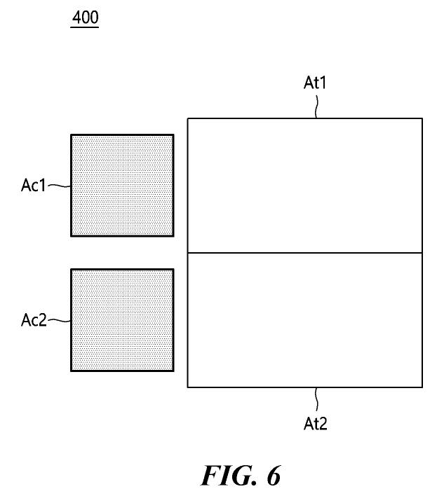

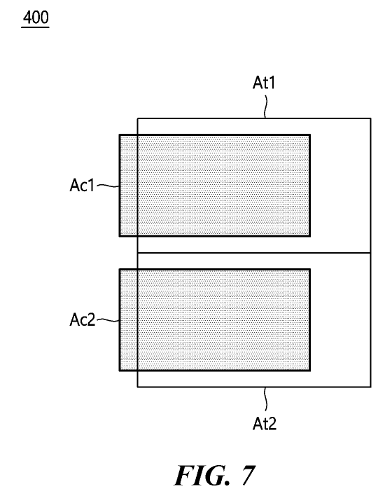

Hereinafter, an arrangement area of the output buffer circuit 400, which is an important circuit component of the gate-in panel circuit 300, is described with reference to FIGS. 6 and 7.

FIG. 6 illustrates the arrangement area of the output buffer circuit 400 of the gate-in panel circuit 300 according to embodiments of the disclosure. In the following description, FIGS. 4 and 5 may also be referred to together. Description overlapping the description of FIGS. 4 and 5 may be omitted.

An area in which the output buffer circuit 400 is disposed may include a first transistor area At1 in which the first transistor T1 is disposed, a second transistor area At2 in which the second transistor T2 is disposed, a first capacitor area Ac1 in which the first capacitor CQ is disposed, and a second capacitor area Ac2 in which the second capacitor CQB is disposed.

To enhance output characteristics of the output buffer circuit 400, each of the first capacitor CQ and the second capacitor CQB needs to have a large capacitance. To increase the capacitance of each of the first capacitor CQ and the second capacitor CQB, each of the first capacitor CQ and the second capacitor CQB needs to be designed to have a large area.

The first capacitor area Ac1 and the second capacitor area Ac2 may not overlap the first transistor area At1 and the second transistor area At2. Accordingly, a panel vertical structure may be simplified, and design of the panel vertical structure may become easier.

However, when the first capacitor area Ac1 and the second capacitor area Ac2 do not overlap the first transistor area At1 and the second transistor area At2, a total area of an area occupied by the output buffer circuit 400 inevitably increases. Accordingly, a size of the non-display area NDA increases, and narrow bezel design may become difficult.

Thus, the display device 100 according to embodiments of the disclosure may further include a gate-in panel circuit structure enabling a narrow bezel. The gate-in panel circuit 300 according to embodiments of the disclosure may include an output buffer circuit structure enabling a narrow bezel. The gate-in panel circuit 300 according to embodiments of the disclosure may include a capacitor structure enabling a narrow bezel.

Hereinafter, the gate-in panel circuit 300 for a narrow bezel according to embodiments of the disclosure and an output buffer circuit structure and a capacitor structure included therein are described.

FIG. 7 illustrates the arrangement area of the output buffer circuit 400 of the gate-in panel circuit 300 according to embodiments of the disclosure. Hereinafter, FIGS. 1 to 6 are referred to together, and description overlapping the description of FIGS. 1 to 6 may be omitted.

Referring to FIG. 7, at least a portion of the first capacitor area Ac1 may overlap at least a portion of the first transistor area At1, or at least a portion of the second capacitor area Ac2 may overlap at least a portion of the second transistor area At2.

Accordingly, at least a portion of the first capacitor CQ may overlap at least a portion of the first transistor T1, or at least a portion of the second capacitor CQB may overlap at least a portion of the second transistor.

Due to the above-described overlapping structure, a total area of an area occupied by the output buffer circuit 400 may be significantly decreased, and as a result, a size of the non-display area NDA may be decreased, and narrow bezel design may become easier.

Hereinafter, the above-described overlapping structure is described in more detail.

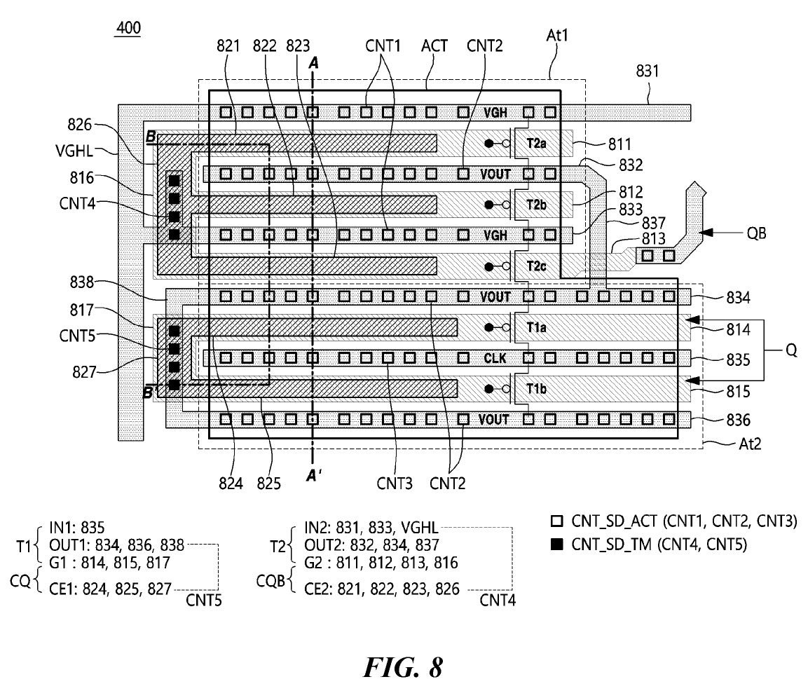

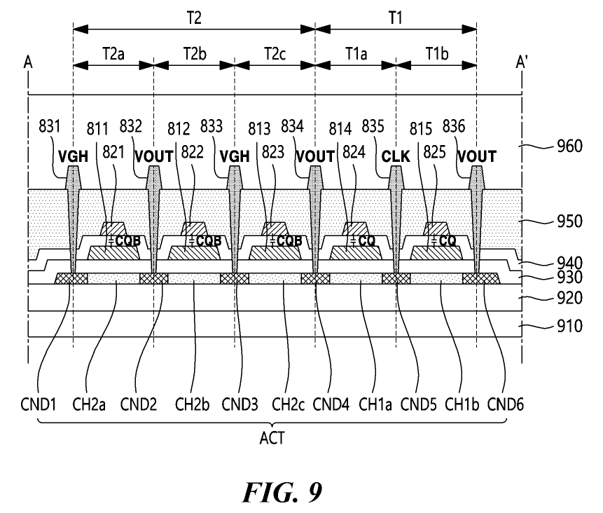

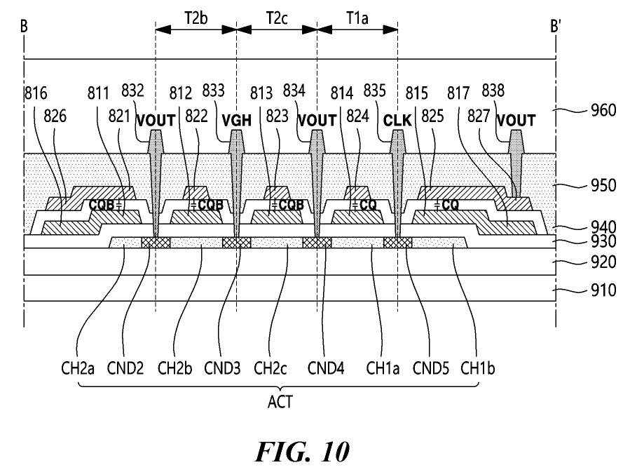

FIGS. 8 to 10 illustrate a planar structure and a vertical structure of the arrangement area of the output buffer circuit 400 of the gate-in panel circuit 300 according to embodiments of the disclosure. FIG. 8 is a plan view illustrating the arrangement area of the output buffer circuit 400, and FIGS. 9 and 10 are cross-sectional views in the arrangement area of the output buffer circuit 400 respectively taken along lines A-A’ and B-B’ in FIG. 8. Hereinafter, FIGS. 1 to 7 are referred to together, and description overlapping the description of FIGS. 1 to 7 may be omitted.

In FIGS. 8 to 10, the first input signal INS1 is a clock signal CLK and the first input signal line INSL1 is a clock signal line CLKL as an example, and the second input signal INS2 is a gate high level voltage VGH and the second input signal line INSL2 is a gate high level voltage line VGHL as an example.

The first transistor T1 and the second transistor T2 may physically share one active layer ACT. The one active layer ACT may include a first channel region CH1a and CH1b of the first transistor T1 and a second channel region CH2a, CH2b, and CH2c of the second transistor. The active layer ACT may be composed of various semiconductor materials. For example, the active layer ACT may include a silicon-based semiconductor material or an oxide-based semiconductor material. In an example, the active layer ACT may include a low temperature poly-crystalline silicon (LTPS) semiconductor material. As another example, the active layer ACT may include an oxide semiconductor material.

According to the sharing structure of the active layer ACT, the first channel region CH1a and CH1b of the first transistor T1 and the second channel region CH2a, CH2b, and CH2c of the second transistor may all be formed by commonly utilizing one active layer ACT, which may help with process optimization.

At least a portion of the first capacitor CQ may overlap at least a portion of the first transistor T1, and at least a portion of the second capacitor CQB may overlap at least a portion of the second transistor T2.

For example, as illustrated in FIGS. 9 and 10, at least a portion of the first capacitor CQ may vertically overlap at least a portion of the first channel region CH1a and CH1b of the first transistor T1, and at least a portion of the second capacitor CQB may vertically overlap at least a portion of the second channel region CH2a, CH2b, and CH2c of the second transistor T2.

Due to such an overlapping structure, an area of the output buffer circuit 400 may be significantly decreased. As a result, a bezel of the display panel 110 may be significantly decreased.

According to the gate-in panel circuit 300 according to embodiments of the disclosure, at least one of the first capacitor CQ and the second capacitor CQB may have a comb shape. Accordingly, the first capacitor CQ and the second capacitor CQB having a large capacitance may be formed without greatly affecting formation of the first transistor T1 and the second transistor T2.

The first capacitor CQ should be formed in association with the first gate electrode G1 of the first transistor T1, and the second capacitor CQB should be formed in association with the second gate electrode G2 of the second transistor T2. Therefore, considering shapes of each of the first capacitor CQ and the second capacitor CQB, each of the first gate electrode G1 of the first transistor T1 and the second gate electrode G2 of the second transistor T2 may have a comb shape.

Accordingly, the first transistor T1 and the second transistor T2, and the first capacitor CQ and the second capacitor CQB may be configured such that at least a portion of the first capacitor area Ac1 overlaps at least a portion of the first transistor area At1 and at least a portion of the second capacitor area Ac2 overlaps at least a portion of the second transistor area At2, within a range where their respective functions are not problematic.

As described above, the first transistor T1 may include the comb-shaped first gate electrode G1, and the first capacitor CQ may include the comb-shaped first capacitor electrode CE1 overlapping at least a portion of the first gate electrode G1.

The first capacitor CQ may be formed between the first gate electrode G1 and the first capacitor electrode CE1. As such, by not forming both two electrodes necessary for forming the first capacitor CQ separately but configuring one of the two electrodes as the first gate electrode G1 of the first transistor T1, a panel stacked structure may become simple, and process optimization may become possible.

The second transistor T2 may include the comb-shaped second gate electrode G2, and the second capacitor CQB may include the comb-shaped second capacitor electrode CE2 overlapping at least a portion of the second gate electrode G2. FIG. 8 illustrates that connection patterns (e.g., a first gate connection pattern 816, a second gate connection pattern 817, a first capacitor connection pattern 826 and a second capacitor connection pattern 827) are formed at one side of the first capacitor CQ, the second capacitor CQB, the first gate electrode G1 and the second gate electrode G2, but the present disclosure is not limited thereto, for example, the connection patterns may be formed at other positions such as a middle location of the first capacitor CQ, the second capacitor CQB, the first gate electrode G1 and the second gate electrode G2.

The second capacitor CQB may be formed between the second gate electrode G2 and the second capacitor electrode CE2. As such, by not forming both two electrodes necessary for forming the second capacitor CQB separately but configuring one of the two electrodes as the second gate electrode G2 of the second transistor T2, a panel stacked structure may become simple, and process optimization may become possible.

Referring to FIGS. 8 to 10, at least a portion of the first capacitor CQ may overlap at least a portion of the first channel region CH1a and CH1b of the first transistor T1 and may be located on the first channel region CH1a and CH1b of the first transistor T1.

Referring to FIGS. 8 to 10, at least a portion of the second capacitor CQB may overlap at least a portion of the second channel region CH2a, CH2b, and CH2c of the second transistor T2 and may be located on the second channel region CH2a, CH2b, and CH2c of the second transistor T2.

According to the above-described structure, the first capacitor CQ may be effectively formed in association with the first transistor T1, and the second capacitor CQB may be effectively formed in association with the second transistor T2.

Referring to FIGS. 8 to 10, a planar structure (panel stacked structure) and a vertical structure for the gate-in panel circuit 300 are described in more detail.

First, a sub transistor structure of each of the first and second transistors T1 and T2 is described.

The first transistor T1 may include the first sub transistor T1a and the second sub transistor T1b connectable in parallel.

The gate electrode of the first sub transistor T1a and the gate electrode of the second sub transistor T1b may be commonly connected to the first control node Q, the input electrode of the first sub transistor T1a and the input electrode of the second sub transistor T1b may be commonly connected to the first input node Nin1, and the output electrode of the first sub transistor T1a and the output electrode of the second sub transistor T1b may be commonly connected to the output node Nout.

The second transistor T2 may include the third sub transistor T2a, the fourth sub transistor T2b, and the fifth sub transistor T2c connectable in parallel.

The gate electrode of the third sub transistor T2a, the gate electrode of the fourth sub transistor T2b, and the gate electrode of the fifth sub transistor T2c may be commonly connected to the second control node QB, the input electrode of the third sub transistor T2a, the input electrode of the fourth sub transistor T2b, and the input electrode of the fifth sub transistor T2c may be commonly connected to the second input node Nin2, and the output electrode of the third sub transistor T2a, the output electrode of the fourth sub transistor T2b, and the output electrode of the fifth sub transistor T2c may be commonly connected to the output node Nout.

Next, an insulation layer structure of the gate-in panel circuit 300 is described.

The display panel 110 may include a first buffer layer 910 on the substrate 111, a second buffer layer 920 on the first buffer layer 910, a gate insulation layer 930 on the second buffer layer 920, a first interlayer insulation layer 940 on the gate insulation layer 930, a second interlayer insulation layer 950 on the first interlayer insulation layer 940, and a planarization layer 960 on the second interlayer insulation layer 950.

In an example, each of the first buffer layer 910, the second buffer layer 920, the gate insulation layer 930, the first interlayer insulation layer 940, and the second interlayer insulation layer 950 may be an inorganic layer (inorganic insulation layer) including an inorganic insulating material. For example, each of the first buffer layer 910, the second buffer layer 920, the gate insulation layer 930, the first interlayer insulation layer 940, and the second interlayer insulation layer 950 may be composed of a single layer or multiple layers of silicon oxide (SiOx) or silicon nitride (SiNx). However, the disclosure is not limited thereto.

As another example, at least one of the first buffer layer 910, the second buffer layer 920, the gate insulation layer 930, the first interlayer insulation layer 940, and the second interlayer insulation layer 950 may be an organic layer (organic insulation layer) including an organic insulating material.

The planarization layer 960 may be an organic layer (organic insulation layer) including an organic insulating material. When the display panel 110 according to embodiments of the disclosure is a self-emitting display panel that emits light by itself, the light emitting element ED may be disposed on the planarization layer 960.

Next, a non-insulation layer structure of the gate-in panel circuit 300 is described.

The display panel 110 may include a semiconductor layer (also referred to as a semiconductor material layer or an active layer) between the second buffer layer 920 and the gate insulation layer 930, a first metal layer between the gate insulation layer 930 and the first interlayer insulation layer 940, a second metal layer between the first interlayer insulation layer 940 and the second interlayer insulation layer 950, and a third metal layer between the second interlayer insulation layer 950 and the planarization layer 960.

The first metal layer may be a metal layer in which the first gate electrode G1 of the first transistor T1 and the second gate electrode G2 of the second transistor T2 are formed. In this sense, the first metal layer is also referred to as a gate metal layer.

The second metal layer may be a metal layer in which the first capacitor electrode CE1 and the second capacitor electrode CE2 are formed. In this sense, the second metal layer is also referred to as a capacitor metal layer.

The third metal layer may be a metal layer in which the first input electrode IN1 and the first output electrode OUT1 of the first transistor T1 and the second input electrode IN2 and the second output electrode OUT2 of the second transistor T2 are formed. In this sense, the third metal layer is also referred to as a source-drain metal layer.

The display panel 110 according to embodiments of the disclosure may include a first type of contact hole CNT_SD_ACT for connecting between the source-drain metal layer SD (third metal layer) and the active layer ACT, and a second type of contact hole CNT_SD_TM for connecting between the source-drain metal layer SD (third metal layer) and the capacitor metal layer TM (second metal layer).

Next, a transistor structure of the gate-in panel circuit 300 is described in more detail.

Referring to FIGS. 8 to 10, the output buffer circuit 400 of the gate-in panel circuit 300 according to embodiments of the disclosure may include the first to sixth source-drain patterns 831, 832, 833, 834, 835, and 836 disposed in the source-drain metal layer, the first to fifth gate patterns 811, 812, 813, 814, and 815 disposed in the gate metal layer, and the active layer ACT.

The first gate pattern 811 may be disposed between the first source-drain pattern 831 and the second source-drain pattern 832. The second gate pattern 812 may be disposed between the second source-drain pattern 832 and the third source-drain pattern 833. The third gate pattern 813 may be disposed between the third source-drain pattern 833 and the fourth source-drain pattern 834. The fourth gate pattern 814 may be disposed between the fourth source-drain pattern 834 and the fifth source-drain pattern 835. The fifth gate pattern 815 may be disposed between the fifth source-drain pattern 835 and the sixth source-drain pattern 836.

The first to third gate patterns 811, 812, and 813 may be integrally formed or electrically connected to each other. The fourth and fifth gate patterns 814 and 815 may be integrally formed or electrically connected to each other.

The first transistor T1 and the second transistor T2 may share the active layer ACT.

The active layer ACT may include a first sub channel region CH1a, a second sub channel region CH1b, a third sub channel region CH2a, a fourth sub channel region CH2b, and a fifth sub channel region CH2c. The first sub channel region CH1a, the second sub channel region CH1b, the third sub channel region CH2a, the fourth sub channel region CH2b, and the fifth sub channel region CH2c may be spaced apart from each other.

The first sub channel region CH1a may be the channel region of the first sub transistor T1a, and the second sub channel region CH1b may be the channel region of the second sub transistor T1b. The first channel region of the first transistor T1 may include the first sub channel region CH1a and the second sub channel region CH1b.

The third sub channel region CH2a may be the channel region of the third sub transistor T2a, the fourth sub channel region CH2b may be the channel region of the fourth sub transistor T2b, and the fifth sub channel region CH2c may be the channel region of the fifth sub transistor T2c. The second channel region of the second transistor T2 may include the third sub channel region CH2a, the fourth sub channel region CH2b, and the fifth sub channel region CH2c.

The active layer ACT may include a first sub connection region CND1 outside the third sub channel region CH2a, a second sub connection region CND2 between the third sub channel region CH2a and the fourth sub channel region CH2b, a third sub connection region CND3 between the fourth sub channel region CH2b and the fifth sub channel region CH2c, a fourth sub connection region CND4 between the fifth sub channel region CH2c and the first sub channel region CH1a, a fifth sub connection region CND5 between the first sub channel region CH1a and the second sub channel region CH1b, and a sixth sub connection region CND6 outside the second sub channel region CH1b.

The first to sixth sub connection regions CND1 to CND6 may be conductorized regions and may be regions to which source electrodes and drain electrodes of the first to sixth sub transistors T1a, T1b, T2a, T2b, and T2c are connected.

The active layer ACT may overlap at least a portion of the first to sixth source-drain patterns 831, 832, 833, 834, 835, and 836 and the first to fifth gate patterns 811, 812, 813, 814, and 815.

The first source-drain pattern 831 may be connected to the first sub connection region CND1 through a first hole of the insulation layers 930, 940, and 950. The second source-drain pattern 832 may be connected to the second sub connection region CND2 through a second hole of the insulation layers 930, 940, and 950. The third source-drain pattern 833 may be connected to the third sub connection region CND3 through a third hole of the insulation layers 930, 940, and 950. The fourth source-drain pattern 834 may be connected to the fourth sub connection region CND4 through a fourth hole of the insulation layers 930, 940, and 950. The fifth source-drain pattern 835 may be connected to the fifth sub connection region CND5 through a fifth hole of the insulation layers 930, 940, and 950. The sixth source-drain pattern 836 may be connected to the sixth sub connection region CND6 through a sixth hole of the insulation layers 930, 940, and 950.

Each of the first hole and the third hole may correspond to a first contact hole CNT1, each of the second hole, the fourth hole, and the sixth hole may correspond to a second contact hole CNT2, and the fifth hole may correspond to a third contact hole CNT3. The first to third contact holes CNT1, CNT2, and CNT3 may be included in the first type of contact hole CNT_SD_ACT.

The first source-drain pattern 831 and the third source-drain pattern 833 may be integrally formed or electrically connected to each other.

The second source-drain pattern 832, the fourth source-drain pattern 834, and the sixth source-drain pattern 836 may be integrally formed or electrically connected to each other.

The fifth source-drain pattern 835 may correspond to the first input electrode IN1 of the first transistor T1.

Regarding the configuration of the first transistor T1, the fourth source-drain pattern 834 and the sixth source-drain pattern 836 may correspond to the first output electrode OUT1 of the first transistor T1, the fourth gate pattern 814 and the fifth gate pattern 815 may correspond to the first gate electrode G1 of the first transistor T1, and accordingly, the first transistor T1 including the first and second sub transistors T1a and T1b may be configured.

Regarding the configuration of the second transistor T2, the first source-drain pattern 831 and the third source-drain pattern 833 may correspond to the second input electrode IN2 of the second transistor T2, the second source-drain pattern 832 and the fourth source-drain pattern 834 may correspond to the second output electrode OUT2 of the second transistor T2, and the first gate pattern 811, the second gate pattern 812, and the third gate pattern 813 may correspond to the second gate electrode G2 of the second transistor T2. Accordingly, the second transistor T2 including the third to fifth sub transistors T2a, T2b, and T2c may be configured.

The second output electrode OUT2 may be electrically connected to the first output electrode OUT1. Accordingly, the first output electrode OUT1 and the second output electrode OUT2 have the same electrical state and may be electrically connected to the output node Nout.

The first source-drain pattern 831 and the third source-drain pattern 833 may be integrally formed or electrically connected to each other and may be electrically connected to the second input node Nin2.

The first source-drain pattern 831 and the third source-drain pattern 833 may be integrally formed with the second input signal line INSL2 or electrically connected to the second input signal line INSL2. Here, the second input signal INS2 may be applied to the second input signal line INSL2. For example, the second input signal INS2 may be a gate high level voltage VGH, and the second input signal line INSL2 may be a gate high level voltage line VGHL.

The second source-drain pattern 832, the fourth source-drain pattern 834, and the sixth source-drain pattern 836 may be integrally formed or electrically connected to each other.

The second source-drain pattern 832 and the fourth source-drain pattern 834 may be electrically connected by a first source-drain connection pattern 837 or may be integrally formed with the first source-drain connection pattern 837.

The fourth source-drain pattern 834 and the sixth source-drain pattern 836 may be electrically connected by a second source-drain connection pattern 838 or may be integrally formed with the second source-drain connection pattern 838.

The second source-drain pattern 832, the fourth source-drain pattern 834, and the sixth source-drain pattern 836 may be electrically connected to the output node Nout. For example, the output node Nout may be electrically connected to a gate line GL disposed in the display area DA. The output signal VOUT output from the output node Nout may be a gate signal Vgate supplied to the gate line GL.

The fifth source-drain pattern 835 may be electrically connected to the first input node Nin1. The fifth source-drain pattern 835 may be electrically connected to the first input signal line INSL1. Here, the first input signal INS1 may be applied to the first input signal line INSL1. For example, the first input signal INS1 may be a clock signal CLK, and the first input signal line INSL1 may be a clock signal line CLKL.

For the configuration of the first gate electrode G1 of the first transistor T1, the fourth gate pattern 814 and the fifth gate pattern 815 may be electrically connected by a second gate connection pattern 817 or may be integrally formed with the second gate connection pattern 817.

For the configuration of the second gate electrode G2 of the second transistor T2, the first gate pattern 811, the second gate pattern 812, and the third gate pattern 813 may be electrically connected by a first gate connection pattern 816 or may be integrally formed with the first gate connection pattern 816.

Referring to FIGS. 8 to 10, the first transistor T1 may include the first sub transistor T1a and the second sub transistor T1b.

The first sub transistor T1a may be constituted by the fourth source-drain pattern 834, the fifth source-drain pattern 835, and the fourth gate pattern 814. The second sub transistor T1b may be constituted by the fifth source-drain pattern 835, the sixth source-drain pattern 836, and the fifth gate pattern 815.

Referring to FIGS. 8 to 10, the second transistor T2 may include the third sub transistor T2a, the fourth sub transistor T2b, and the fifth sub transistor T2c.

The third sub transistor T2a may be constituted by the first source-drain pattern 831, the second source-drain pattern 832, and the first gate pattern 811. The fourth sub transistor T2b may be constituted by the second source-drain pattern 832, the third source-drain pattern 833, and the second gate pattern 812. The fifth sub transistor T2c may be constituted by the third source-drain pattern 833, the fourth source-drain pattern 834, and the third gate pattern 813.

Next, a capacitor structure of the gate-in panel circuit 300 is described in more detail.

As described above, the display device 100 according to embodiments of the disclosure may include the source-drain metal layer in which the first to sixth source-drain patterns 831 to 836 are disposed and the gate metal layer in which the first to fifth gate patterns 811 to 815 are disposed.

The display device 100 according to embodiments of the disclosure may further include a capacitor metal layer to form the first capacitor CQ and the second capacitor CQB.

The display device 100 according to embodiments of the disclosure may further include the first to fifth capacitor patterns 821 to 825 disposed in the capacitor metal layer to form the first capacitor CQ and the second capacitor CQB.

The first capacitor pattern 821 may be disposed between the first source-drain pattern 831 and the second source-drain pattern 832 and may overlap at least a portion of the first gate pattern 811. The second capacitor pattern 822 may be disposed between the second source-drain pattern 832 and the third source-drain pattern 833 and may overlap at least a portion of the second gate pattern 812. The third capacitor pattern 823 may be disposed between the third source-drain pattern 833 and the fourth source-drain pattern 834 and may overlap at least a portion of the third gate pattern 813.

The fourth capacitor pattern 824 may be disposed between the fourth source-drain pattern 834 and the fifth source-drain pattern 835 and may overlap at least a portion of the fourth gate pattern 814. The fifth capacitor pattern 825 may be disposed between the fifth source-drain pattern 835 and the sixth source-drain pattern 836 and may overlap at least a portion of the fifth gate pattern 815.

For the configuration of the first capacitor CQ, the fourth and fifth capacitor patterns 824 and 825 may be integrally formed or electrically connected to each other to constitute the first capacitor electrode CE1. The first capacitor electrode CE1 may be electrically connected to the output node Nout electrically corresponding to the output node Nout. In other words, the first capacitor electrode CE1 may be electrically connected to the first output electrode OUT1 through at least one fifth contact hole CNT5. The at least one fifth contact hole CNT5 may be included in the second type of contact hole CNT_SD_TM.

The fourth and fifth capacitor patterns 824 and 825 may be electrically connected by a second capacitor connection pattern 827 or may be integrally formed with the second capacitor connection pattern 827.

The first capacitor CQ may be formed between the first gate electrode G1 and the first capacitor electrode CE1. An area in which the first capacitor CQ is disposed may be the first capacitor area Ac1.

For the configuration of the second capacitor CQB, the first to third capacitor patterns 821, 822, and 823 may be integrally formed or electrically connected to each other to constitute the second capacitor electrode CE2. The second capacitor electrode CE2 may be electrically connected to the second input node Nin2 electrically corresponding to the second input node Nin2. In other words, the second capacitor electrode CE2 may be electrically connected to the second input electrode IN2 through at least one fourth contact hole CNT4. The at least one fourth contact hole CNT4 may be included in the second type of contact hole CNT_SD_TM.

The first to third capacitor patterns 821, 822, and 823 may be electrically connected by a first capacitor connection pattern 826 or may be integrally formed with the first capacitor connection pattern 826.

The second capacitor CQB may be formed between the second gate electrode G2 and the second capacitor electrode CE2. An area in which the second capacitor CQB is disposed may be the second capacitor area Ac2.

The gate-in panel circuit 300 according to embodiments of the disclosure described above may output a gate signal Vgate as an output signal VOUT to a gate line GL disposed in the display area DA.

The gate line GL may be connected to a subpixel SP disposed in the display area DA. More specifically, the gate line GL may be electrically connected to a gate electrode of a transistor in the subpixel SP. For example, a gate electrode of the scan transistor ST in the subpixel SP of FIG. 2 may be electrically connected to a scan line SCL that is one type of gate line GL.

The gate signal Vgate output from the gate-in panel circuit 300 may be applied to a gate electrode of a transistor (e.g., the scan transistor ST) in the subpixel SP through the gate line GL.

A vertical structure of the first and second transistors T1 and T2 and the first and second capacitors CQ and CQB included in the gate-in panel circuit 300 according to embodiments of the disclosure described above may correspond to a vertical structure of a transistor and a capacitor included in a subpixel SP in the display area DA. In this regard, hereinafter, a vertical structure of a transistor and a capacitor included in the subpixel SP is described.

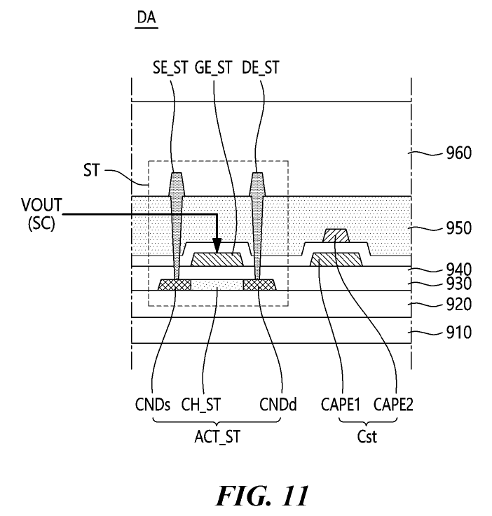

FIG. 11 is a cross-sectional view in the display area DA of the display panel 110 according to embodiments of the disclosure.

Referring to FIG. 11, the subpixel SP disposed in the display area DA of the display panel 110 may include a transistor and a capacitor. For example, the subpixel SP may include a scan transistor ST and a storage capacitor Cst. Hereinafter, the scan transistor ST and the storage capacitor Cst are described as an example.

The scan transistor ST may include an active layer ACT_ST, a source electrode SE_ST, a drain electrode DE_ST, and a gate electrode GE_ST. A scan signal SC that is an output signal VOUT output from the gate-in panel circuit 300 may be applied to the gate electrode GE_ST of the scan transistor ST.

Referring to FIG. 11, the scan transistor ST may have the same layer stack as the first transistor T1 and the second transistor T2 in the gate-in panel circuit 300.

More specifically, the active layer ACT_ST of the scan transistor ST may be located in the same layer as the active layer ACT of the first and second transistors T1 and T2.

The active layer ACT_ST of the scan transistor ST may include a channel region CH_ST, a first connection region CNDs on one side of the channel region CH_ST, and a second connection region CNDd on the other side of the channel region CH_ST. For example, the first connection region CNDs and the second connection region CNDd may be conductorized regions.

The active layer ACT_ST of the scan transistor ST may include the same semiconductor material as the active layer ACT shared by the first and second transistors T1 and T2 included in the gate-in panel circuit 300.

The source electrode SE_ST may be connected to the first connection region CNDs through a first hole of the insulation layers 930, 940, and 950. The drain electrode DE_ST may be connected to the second connection region CNDd through a second hole of the insulation layers 930, 940, and 950.

The gate electrode GE_ST of the scan transistor ST may be located in the same gate metal layer as the first and second gate electrodes G1 and G2 of the first and second transistors T1 and T2.

The source electrode SE_ST and the drain electrode DE_ST of the scan transistor ST may be located in the same source-drain metal layer as the first and second input electrodes IN1 and IN2 and the first and second output electrodes OUT1 and OUT2 of the first and second transistors T1 and T2.

Referring to FIG. 11, the storage capacitor Cst may have the same layer stack as the first capacitor CQ and the second capacitor CQB in the gate-in panel circuit 300.

Each of the first capacitor CQ and the second capacitor CQB in the gate-in panel circuit 300 may be formed between the gate metal layer and the capacitor metal layer, and similarly, the storage capacitor Cst may be formed between the gate metal layer and the capacitor metal layer.

The storage capacitor Cst may include a lower capacitor electrode CAPE1 and an upper capacitor electrode CAPE2.

The first and second capacitor electrodes CE1 and CE2 of the first capacitor CQ and the second capacitor CQB in the gate-in panel circuit 300 may be located in the same capacitor metal layer. Similarly, the upper capacitor electrode CAPE2 of the storage capacitor Cst may be disposed in the capacitor metal layer.

The remaining one electrode except for the first capacitor electrode CE1 among two electrodes forming the first capacitor CQ (e.g., the first gate electrode G1) and the remaining one electrode except for the second capacitor electrode CE2 among two electrodes forming the second capacitor CQB (e.g., the second gate electrode G2) may be disposed in the gate metal layer. Similarly, the lower capacitor electrode CAPE1 of the storage capacitor Cst may be disposed in the gate metal layer.

According to embodiments of the disclosure described above, a gate-in panel circuit 300 and a display device 100 having a structure capable of reducing a bezel may be provided.

According to embodiments of the disclosure, a gate-in panel circuit 300 and a display device 100 having a capacitor structure (bootstrap capacitor structure) capable of implementing large capacitance and a small bezel may be provided.

According to embodiments of the disclosure, a gate-in panel circuit 300 and a display device 100 having excellent signal output characteristics may be provided.

According to embodiments of the disclosure, a gate-in panel circuit 300 and a display device 100 having a structure capable of process optimization may be provided.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

The exemplary embodiments of the present disclosure can also be described as follows:

A display device according to embodiments of the disclosure includes a first transistor configured to control a connection between a first input node to which a first input signal is input and an output node from which an output signal is output, according to the voltage of a first control node; and a second transistor configured to control a connection between a second input node to which a second input signal is input and the output node, according to the voltage of a second control node, the display device may further comprise at least one of a first capacitor between the first control node and the output node and a second capacitor between the second control node and the second input node, and at least a portion of the first capacitor may overlap at least a portion of the first transistor, and at least a portion of the second capacitor may overlap at least a portion of the second transistor.

The display device may further include one active layer shared by the first transistor and the second transistor, the one active layer may include a first channel region of the first transistor and a second channel region of the second transistor.

At least one of the first capacitor and the second capacitor may have a comb shape.

At least a portion of the first capacitor may overlap at least a portion of a first channel region of the first transistor, and at least a portion of the second capacitor may overlap at least a portion of a second channel region of the second transistor.

The first transistor may include a comb-shaped first gate electrode, the second transistor may include a comb-shaped second gate electrode, the first capacitor may include a comb-shaped first capacitor electrode overlapping at least a portion of the first gate electrode, and the first capacitor may be formed between the first gate electrode and the first capacitor electrode, and the second capacitor may include a comb-shaped second capacitor electrode overlapping at least a portion of the second gate electrode, and the second capacitor may be formed between the second gate electrode and the second capacitor electrode.

At least a portion of the first capacitor may be located on a first channel region of the first transistor, and at least a portion of the second capacitor may be located on a second channel region of the second transistor.

The first input signal may include a section having a voltage different from a voltage of the second input signal.

The display device may further include: a gate line; a subpixel connected to the gate line; and a gate-in panel circuit supplying a gate signal to the gate line, the gate-in panel circuit may include the first transistor, the second transistor, the first capacitor, and the second capacitor, and the first input signal may be a clock signal, the second input signal may be a gate low level voltage, and the output signal may correspond to the gate signal.

The display device may further include: first to sixth source-drain patterns disposed in a source-drain metal layer; a first gate pattern disposed in a gate metal layer and disposed between the first source-drain pattern and the second source-drain pattern; a second gate pattern disposed in the gate metal layer and disposed between the second source-drain pattern and the third source-drain pattern; a third gate pattern disposed in the gate metal layer and disposed between the third source-drain pattern and the fourth source-drain pattern; a fourth gate pattern disposed in the gate metal layer and disposed between the fourth source-drain pattern and the fifth source-drain pattern; a fifth gate pattern disposed in the gate metal layer and disposed between the fifth source-drain pattern and the sixth source-drain pattern; and an active layer overlapping at least a portion of the first to sixth source-drain patterns and the first to fifth gate patterns, the first source-drain pattern and the third source-drain pattern may be integrally formed or electrically connected to each other, and the second source-drain pattern, the fourth source-drain pattern, and the sixth source-drain pattern may be integrally formed or electrically connected to each other, the first to third gate patterns may be integrally formed or electrically connected to each other, and the fourth and fifth gate patterns may be integrally formed or electrically connected to each other, the fifth source-drain pattern may correspond to a first input electrode of the first transistor, the fourth source-drain pattern and the sixth source-drain pattern may correspond to a first output electrode of the first transistor, the fourth gate pattern and the fifth gate pattern may correspond to a first gate electrode of the first transistor, the first source-drain pattern and the third source-drain pattern may correspond to a second input electrode of the second transistor, the second source-drain pattern and the fourth source-drain pattern correspond to a second output electrode of the second transistor, and the second output electrode may be electrically connected to the first output electrode, and the first gate pattern, the second gate pattern, and the third gate pattern may correspond to a second gate electrode of the second transistor.

The first source-drain pattern and the third source-drain pattern may be electrically connected to the second input node, the second source-drain pattern, the fourth source-drain pattern, and the sixth source-drain pattern may be electrically connected to the output node, and the fifth source-drain pattern may be electrically connected to the first input node.

The display device may further include: a first capacitor pattern disposed in a capacitor metal layer and disposed between the first source-drain pattern and the second source-drain pattern and overlapping at least a portion of the first gate pattern; a second capacitor pattern disposed in the capacitor metal layer and disposed between the second source-drain pattern and the third source-drain pattern and overlapping at least a portion of the second gate pattern; a third capacitor pattern disposed in the capacitor metal layer and disposed between the third source-drain pattern and the fourth source-drain pattern and overlapping at least a portion of the third gate pattern; a fourth capacitor pattern disposed in the capacitor metal layer and disposed between the fourth source-drain pattern and the fifth source-drain pattern and overlapping at least a portion of the fourth gate pattern; and a fifth capacitor pattern disposed in the capacitor metal layer and disposed between the fifth source-drain pattern and the sixth source-drain pattern and overlapping at least a portion of the fifth gate pattern, the fourth and fifth capacitor patterns may be integrally formed or electrically connected to each other to constitute a first capacitor electrode, and the first to third capacitor patterns may be integrally formed or electrically connected to each other to constitute a second capacitor electrode.

The first capacitor may be formed between the first gate electrode and the first capacitor electrode, and the second capacitor may be formed between the second gate electrode and the second capacitor electrode.

The first capacitor electrode may be electrically connected to the first output electrode, and the second capacitor electrode may be electrically connected to the second input electrode.

The first transistor may include a first sub transistor and a second sub transistor, the first sub transistor may be constituted by the fourth source-drain pattern, the fifth source-drain pattern, and the fourth gate pattern, the second sub transistor may be constituted by the fifth source-drain pattern, the sixth source-drain pattern, and the fifth gate pattern, the second transistor may include a third sub transistor, a fourth sub transistor, and a fifth sub transistor, the third sub transistor may be constituted by the first source-drain pattern, the second source-drain pattern, and the first gate pattern, the fourth sub transistor may be constituted by the second source-drain pattern, the third source-drain pattern, and the second gate pattern, and the fifth sub transistor may be constituted by the third source-drain pattern, the fourth source-drain pattern, and the third gate pattern.

The first and second sub transistors may be connected in parallel, and the third to fifth sub transistors may be connected in parallel.

The display device may further include a substrate including a display area and a non-display area, the first transistor, the second transistor, the first capacitor, and the second capacitor may be disposed on the substrate and located in the non-display area.

The display device may further include a subpixel disposed in the display area and including a transistor and a capacitor, the transistor may include a gate electrode to which the output signal is applied and has the same layer stack as the first transistor and the second transistor, and the capacitor may have the same layer stack as the first capacitor and the second capacitor.

During a first period, the first transistor may be turned on and the second transistor may be turned off, so that the first input signal may output to the output node through the first transistor, and during a second period that is a preceding period or a subsequent period of the first period, the first transistor may be turned off and the second transistor may be turned on, so that the second input signal may output to the output node through the second transistor.

Each of the first capacitor and the second capacitor may be a bootstrap capacitor.

The first capacitor electrode may be integrally formed with the first output electrode, and the second capacitor electrode may be integrally with the second input electrode.

At least one of the first transistor and the second transistor may be composed of two or more sub transistors.

The second capacitor may include a first capacitor pattern, a second capacitor pattern, and a third capacitor pattern, the second transistor may include a third sub transistor, a fourth sub transistor, and a fifth sub transistor, and the first capacitor pattern, the second capacitor pattern and the third capacitor pattern may respectively overlap at least a portion of a first gate pattern of the third sub transistor, at least a portion of a second gate pattern of the fourth sub transistor, and at least a portion of a third gate pattern of the fifth sub transistor.

The second capacitor may further include a first capacitor connection pattern electrically connects the first capacitor pattern, the second capacitor pattern, and the third capacitor pattern, the second transistor may further include a first gate connection pattern electrically connects the first gate pattern, the second gate pattern and the third gate pattern, and the first capacitor connection pattern may overlap at least a portion of the first gate connection pattern.

The first capacitor may include a fourth capacitor pattern, and a fifth capacitor pattern, the first transistor may include a first sub transistor, and a second sub transistor, and the fourth capacitor pattern, and the fifth capacitor pattern may respectively overlap at least a portion of a fourth gate pattern of the first sub transistor, and at least a portion of a fifth gate pattern of the second sub transistor.

The first capacitor may further include a second capacitor connection pattern electrically connects the fourth capacitor pattern and the fifth capacitor pattern, the first transistor may further include a second gate connection pattern electrically connects the fourth gate pattern and the fifth gate pattern, and the second capacitor connection pattern may overlap at least a portion of the second gate connection pattern.

A gate-in panel circuit may include: a first transistor controlling a connection between a first input node to which a first input signal is input and an output node from which an output signal is output, according to the voltage of a first control node; and a second transistor controlling a connection between a second input node to which a second input signal is input and the output node, according to the voltage of a second control node, the gate-in panel circuit may further include at least one of a first capacitor having at least a portion disposed on a first channel region of the first transistor and a second capacitor having at least a portion disposed on a second channel region of the second transistor.

At least one of the first capacitor and the second capacitor may have a comb shape.

The first transistor may include a comb-shaped first gate electrode, the first capacitor may include a comb-shaped first capacitor electrode overlapping at least a portion of the first gate electrode, the first capacitor may be formed between the first gate electrode and the first capacitor electrode, the second transistor may include a comb-shaped second gate electrode, the second capacitor may include a comb-shaped second capacitor electrode overlapping at least a portion of the second gate electrode, and the second capacitor may be formed between the second gate electrode and the second capacitor electrode.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a first transistor configured to control a connection between a first input node to which a first input signal is input and an output node from which an output signal is output, according to a voltage of a first control node; and
a second transistor configured to control a connection between a second input node to which a second input signal is input and the output node, according to a voltage of a second control node,
wherein the display device further comprises at least one of a first capacitor between the first control node and the output node and a second capacitor between the second control node and the second input node, and wherein at least a portion of the first capacitor overlaps at least a portion of the first transistor, and at least a portion of the second capacitor overlaps at least a portion of the second transistor.

2. The display device of claim 1, further comprising one active layer shared by the first transistor and the second transistor, wherein the one active layer includes a first channel region of the first transistor and a second channel region of the second transistor.

3. The display device of claim 1, wherein at least one of the first capacitor and the second capacitor has a comb shape.

4. The display device of claim 1, wherein at least a portion of the first capacitor overlaps at least a portion of a first channel region of the first transistor, and at least a portion of the second capacitor overlaps at least a portion of a second channel region of the second transistor.

5. The display device of claim 1, wherein the first transistor includes a comb-shaped first gate electrode,
wherein the second transistor includes a comb-shaped second gate electrode,
wherein the first capacitor includes a comb-shaped first capacitor electrode overlapping at least a portion of the first gate electrode, and the first capacitor is formed between the first gate electrode and the first capacitor electrode, and
wherein the second capacitor includes a comb-shaped second capacitor electrode overlapping at least a portion of the second gate electrode, and the second capacitor is formed between the second gate electrode and the second capacitor electrode.

6. The display device of claim 1, wherein at least a portion of the first capacitor is located on a first channel region of the first transistor, and at least a portion of the second capacitor is located on a second channel region of the second transistor.

7. The display device of claim 1, wherein the first input signal includes a section having a voltage different from a voltage of the second input signal.

8. The display device of claim 1, further comprising:
a gate line;
a subpixel connected to the gate line; and
a gate-in panel circuit supplying a gate signal to the gate line,
wherein the gate-in panel circuit includes the first transistor, the second transistor, the first capacitor, and the second capacitor, and
wherein the first input signal is a clock signal, the second input signal is a gate low level voltage, and the output signal corresponds to the gate signal.

9. The display device of claim 1, further comprising:
first to sixth source-drain patterns disposed in a source-drain metal layer;
a first gate pattern disposed in a gate metal layer and disposed between the first source-drain pattern and the second source-drain pattern;
a second gate pattern disposed in the gate metal layer and disposed between the second source-drain pattern and the third source-drain pattern;
a third gate pattern disposed in the gate metal layer and disposed between the third source-drain pattern and the fourth source-drain pattern;
a fourth gate pattern disposed in the gate metal layer and disposed between the fourth source-drain pattern and the fifth source-drain pattern;
a fifth gate pattern disposed in the gate metal layer and disposed between the fifth source-drain pattern and the sixth source-drain pattern; and
an active layer overlapping at least a portion of the first to sixth source-drain patterns and the first to fifth gate patterns,
wherein the first source-drain pattern and the third source-drain pattern are integrally formed or electrically connected to each other, and the second source-drain pattern, the fourth source-drain pattern, and the sixth source-drain pattern are integrally formed or electrically connected to each other,
wherein the first to third gate patterns are integrally formed or electrically connected to each other, and the fourth and fifth gate patterns are integrally formed or electrically connected to each other,
wherein the fifth source-drain pattern corresponds to a first input electrode of the first transistor,
wherein the fourth source-drain pattern and the sixth source-drain pattern correspond to a first output electrode of the first transistor,
wherein the fourth gate pattern and the fifth gate pattern correspond to a first gate electrode of the first transistor,
wherein the first source-drain pattern and the third source-drain pattern correspond to a second input electrode of the second transistor,
wherein the second source-drain pattern and the fourth source-drain pattern correspond to a second output electrode of the second transistor, and the second output electrode is electrically connected to the first output electrode, and
wherein the first gate pattern, the second gate pattern, and the third gate pattern correspond to a second gate electrode of the second transistor.

10. The display device of claim 9, wherein the first source-drain pattern and the third source-drain pattern are electrically connected to the second input node,
wherein the second source-drain pattern, the fourth source-drain pattern, and the sixth source-drain pattern are electrically connected to the output node, and
wherein the fifth source-drain pattern is electrically connected to the first input node.

11. The display device of claim 9, further comprising:
a first capacitor pattern disposed in a capacitor metal layer and disposed between the first source-drain pattern and the second source-drain pattern and overlapping at least a portion of the first gate pattern;
a second capacitor pattern disposed in the capacitor metal layer and disposed between the second source-drain pattern and the third source-drain pattern and overlapping at least a portion of the second gate pattern;
a third capacitor pattern disposed in the capacitor metal layer and disposed between the third source-drain pattern and the fourth source-drain pattern and overlapping at least a portion of the third gate pattern;
a fourth capacitor pattern disposed in the capacitor metal layer and disposed between the fourth source-drain pattern and the fifth source-drain pattern and overlapping at least a portion of the fourth gate pattern; and
a fifth capacitor pattern disposed in the capacitor metal layer and disposed between the fifth source-drain pattern and the sixth source-drain pattern and overlapping at least a portion of the fifth gate pattern, wherein the fourth and fifth capacitor patterns are integrally formed or electrically connected to each other to constitute a first capacitor electrode, and wherein the first to third capacitor patterns are integrally formed or electrically connected to each other to constitute a second capacitor electrode.

12. The display device of claim 11, wherein the first capacitor is between the first gate electrode and the first capacitor electrode, and the second capacitor is between the second gate electrode and the second capacitor electrode.

13. The display device of claim 12, wherein the first capacitor electrode is electrically connected to the first output electrode, and
wherein the second capacitor electrode is electrically connected to the second input electrode.

14. The display device of claim 9, wherein the first transistor includes a first sub transistor and a second sub transistor,
wherein the first sub transistor is constituted by the fourth source-drain pattern, the fifth source-drain pattern, and the fourth gate pattern,
wherein the second sub transistor is constituted by the fifth source-drain pattern, the sixth source-drain pattern, and the fifth gate pattern,
wherein the second transistor includes a third sub transistor, a fourth sub transistor, and a fifth sub transistor,
wherein the third sub transistor is constituted by the first source-drain pattern, the second source-drain pattern, and the first gate pattern,
wherein the fourth sub transistor is constituted by the second source-drain pattern, the third source-drain pattern, and the second gate pattern, and
wherein the fifth sub transistor is constituted by the third source-drain pattern, the fourth source-drain pattern, and the third gate pattern.

15. The display device of claim 14, wherein the first and second sub transistors are connected in parallel, and
wherein the third to fifth sub transistors are connected in parallel.

16. The display device of claim 1, further comprising a substrate including a display area and a non-display area,
wherein the first transistor, the second transistor, the first capacitor, and the second capacitor are disposed on the substrate and located in the non-display area.

17. The display device of claim 16, further comprising a subpixel disposed in the display area and including a transistor and a capacitor,
wherein the transistor includes a gate electrode to which the output signal is applied and has a same layer stack as the first transistor and the second transistor, and
wherein the capacitor has a same layer stack as the first capacitor and the second capacitor.

18. The display device of claim 1, wherein during a first period, the first transistor is turned on and the second transistor is turned off, so that the first input signal is output to the output node through the first transistor, and
wherein during a second period that is a preceding period or a subsequent period of the first period, the first transistor is turned off and the second transistor is turned on, so that the second input signal is output to the output node through the second transistor.

19. The display device of claim 1, wherein each of the first capacitor and the second capacitor is a bootstrap capacitor.

20. The display device of claim 13, wherein the first capacitor electrode is integrally formed with the first output electrode, and
the second capacitor electrode is integrally with the second input electrode.

21. The display device of claim 1, wherein at least one of the first transistor and the second transistor is composed of two or more sub transistors.

22. The display device of claim 1, wherein the second capacitor includes a first capacitor pattern, a second capacitor pattern, and a third capacitor pattern,
wherein the second transistor includes a third sub transistor, a fourth sub transistor, and a fifth sub transistor, and
wherein the first capacitor pattern, the second capacitor pattern and the third capacitor pattern respectively overlap at least a portion of a first gate pattern of the third sub transistor, at least a portion of a second gate pattern of the fourth sub transistor, and at least a portion of a third gate pattern of the fifth sub transistor.

23. The display device of claim 22, wherein the second capacitor further includes a first capacitor connection pattern electrically connects the first capacitor pattern, the second capacitor pattern, and the third capacitor pattern,
wherein the second transistor further includes a first gate connection pattern electrically connects the first gate pattern, the second gate pattern and the third gate pattern, and
wherein the first capacitor connection pattern overlaps at least a portion of the first gate connection pattern.

24. The display device of claim 1, wherein the first capacitor includes a fourth capacitor pattern, and a fifth capacitor pattern,
wherein the first transistor includes a first sub transistor, and a second sub transistor, and
wherein the fourth capacitor pattern, and the fifth capacitor pattern respectively overlap at least a portion of a fourth gate pattern of the first sub transistor, and at least a portion of a fifth gate pattern of the second sub transistor.

25. The display device of claim 24, wherein the first capacitor further includes a second capacitor connection pattern electrically connects the fourth capacitor pattern and the fifth capacitor pattern,
wherein the first transistor further includes a second gate connection pattern electrically connects the fourth gate pattern and the fifth gate pattern, and
wherein the second capacitor connection pattern overlaps at least a portion of the second gate connection pattern.

26. A gate-in panel circuit, comprising:
a first transistor configured to control a connection between a first input node to which a first input signal is input and an output node from which an output signal is output, according to a voltage of a first control node, the first transistor having a first channel region; and
a second transistor configured to control a connection between a second input node to which a second input signal is input and the output node, according to a voltage of a second control node, the second transistor having a second channel region,
wherein the gate-in panel circuit further comprises at least one of a first capacitor having at least a portion disposed on the first channel region of the first transistor and a second capacitor having at least a portion disposed on the second channel region of the second transistor.

27. The gate-in panel circuit of claim 26, wherein at least one of the first capacitor and the second capacitor has a comb shape.

28. The gate-in panel circuit of claim 26, wherein the first transistor includes a comb-shaped first gate electrode,
wherein the first capacitor includes a comb-shaped first capacitor electrode overlapping at least a portion of the first gate electrode,
wherein the first capacitor is formed between the first gate electrode and the first capacitor electrode,
wherein the second transistor includes a comb-shaped second gate electrode, wherein the second capacitor includes a comb-shaped second capacitor electrode overlapping at least a portion of the second gate electrode, and
wherein the second capacitor is formed between the second gate electrode and the second capacitor electrode.
